(19) United States
(12) Patent Application Publication
(10) Pub. No.: US 2026/0227462 A1
(43) Pub. Date: Aug. 6, 2026

(54) INSPECTION DEVICE, INSPECTION METHOD, AND METHOD FOR MANUFACTURING BATTERY

(71) Applicant: Kabushiki Kaisha Toshiba, Kawasaki-shi Kanagawa (JP)

(72) Inventors: Yoshihiro HIGASHI, Komatsu Ishikawa (JP); Akira KIKITSU, Yokohama Kanagawa (JP); Satoshi SHIROTORI, Yokohama Kanagawa (JP)

(73) Assignee: Kabushiki Kaisha Toshiba, Kawasaki-shi Kanagawa (JP)

(21) Appl. No.: 19/447,236

(22) Filed: Jan. 13, 2026

(30) Foreign Application Priority Data
Feb. 6, 2025 (JP) 2025-018600

(51) Int. Cl. G01R 33/00; G01R 33/10; H01M 10/04; H01M 10/48

(52) U.S. Cl. CPC G01R 33/0029; G01R 33/0005; G01R 33/10; H01M 10/0422; H01M 10/48

(57) ABSTRACT

According to one embodiment, an inspection device includes an acquisitor configured to acquire data obtained from an inspection target, and a processor configured to perform a first operation of processing the data acquired by the acquisitor. The data includes a first magnetic field data represented by a first coordinate in a first direction and a second coordinate in a circumferential direction around a first axis along the first direction. The processor is configured to inspect the inspection target based on a first inspection data based on the first magnetic field data in the first operation.

### CROSS-REFERENCE TO RELATED APPLICATIONS

This application is based upon and claims the benefit of priority from Japanese Patent Application No. 2025-018600, filed on February 6, 2025; the entire contents of which are incorporated herein by reference.

### FIELD

Embodiments described herein relate generally to an inspection device, an inspection method, and a method for manufacturing a battery.

### BACKGROUND

For example, an inspection target such as a battery is inspected by detecting a magnetic field generated from the inspection target. Higher accuracy of the inspection is desired.

### BRIEF DESCRIPTION OF THE DRAWINGS

FIG. 1 is a schematic diagram illustrating an inspection device according to a first embodiment;

FIG. 2 is a flowchart illustrating the operation of the inspection device according to the first embodiment;

FIGS. 3A to 3C are schematic diagrams illustrating the inspection device according to the first embodiment;

FIGS. 4A to 4C are schematic diagrams illustrating the inspection device according to the first embodiment;

FIGS. 5A and 5B are schematic diagrams illustrating the inspection device according to the first embodiment; and

FIG. 6 is a flow chart illustrating a method for manufacturing a battery according to a third embodiment.

### DETAILED DESCRIPTION

According to one embodiment, an inspection device includes an acquisitor configured to acquire data obtained from an inspection target, and a processor configured to perform a first operation of processing the data acquired by the acquisitor. The data includes a first magnetic field data represented by a first coordinate in a first direction and a second coordinate in a circumferential direction around a first axis along the first direction. The processor is configured to inspect the inspection target based on a first inspection data based on the first magnetic field data in the first operation.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

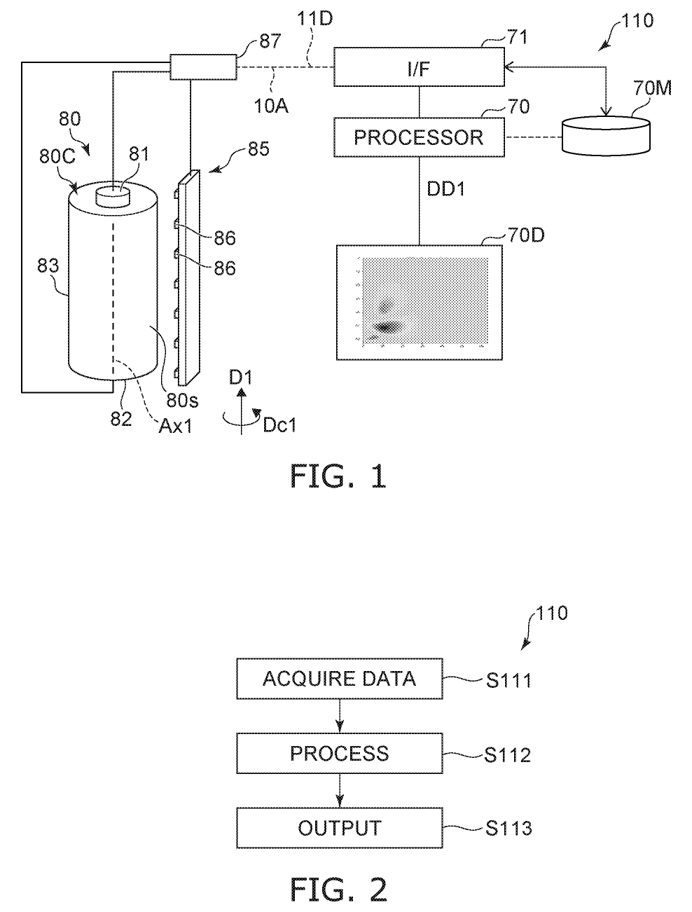

FIG. 1 is a schematic diagram illustrating an inspection device according to a first embodiment.

FIG. 2 is a flowchart illustrating the operation of the inspection device according to the first embodiment.

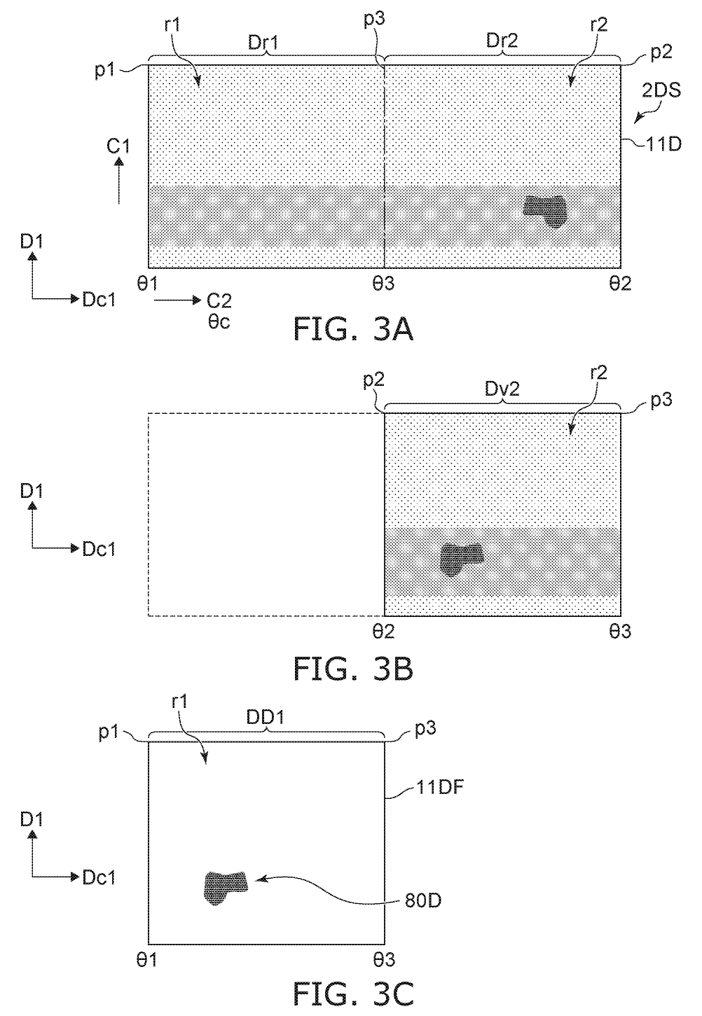

FIGS. 3A to 3C are schematic diagrams illustrating the inspection device according to the first embodiment.

As shown in FIG. 1, an inspection device 110 according to the embodiment includes an acquisitor 71 and a processor 70. The acquisitor 71 is configured to acquire data 10A obtained from an inspection target 80. The processor 70 is configured to perform a first operation of processing the data 10A acquired by the acquisitor 71. The acquisitor 71 is, for example, an interface. The processor 70 may be, for example, a processing circuit (e.g., an electrical circuit).

The data 10A includes a first magnetic field data 11D. In the first operation, the processor 70 is configured to inspect the inspection target 80 based on a first inspection data DD1 based on the first magnetic field data 11D.

FIG. 2 illustrates an example of an inspection method performed by the inspection device 110. As shown in FIG. 2, for example, the acquisitor 71 acquires the data 10A (step S111). For example, the processor 70 processes the data 10A (step S112). For example, the processor 70 outputs a processing result (step S113). The processing result includes an inspection result.

In one example, the inspection target 80 may be a battery 80C. The battery 80C may include, for example, a first electrode 81, a second electrode 82, and a battery portion 83. The battery portion 83 is provided, for example, between the first electrode 81 and the second electrode 82.

As shown in FIG. 1, the inspection target 80 is, for example, cylindrical along a first direction D1.

In one example, in inspecting the battery 80C, a voltage is applied between the first electrode 81 and the second electrode 82. The application of the voltage causes a current to flow between the first electrode 81 and the second electrode 82. The current generates a magnetic field. The generated magnetic field is detected by the magnetic field sensor 85. The magnetic field sensor 85 may include a sensor element 86 and a controller 87. The relative position between the sensor element 86 and the inspection target 80 is changed.

In this example, a plurality of sensor elements 86 are provided. The plurality of sensor elements 86 may be arranged along the first direction D1.

The controller 87 may be configured to, for example, control a change in the relative position between the magnetic field sensor 85 and the inspection target 80. For example, the inspection target 80 may rotate along an axis along the first direction D1. The magnetic field sensor 85 may move around the inspection target 80. As described below, the plurality of sensor elements 86 may be arranged along a circumferential direction Dc1 around the inspection target 80.

The controller 87 may be configured to process, for example, a signal obtained from the sensor element 86. The signal processing may include, for example, amplification. The signal processing may include any processing including, for example, A/D conversion. The above magnetic field data (such as the first magnetic field data 11D) is supplied, for example, from the controller 87 to the acquisitor 71.

Communication (transmission and reception of data) between the magnetic field sensor 85 and the acquisitor 71 can be performed by any method, being wired or wireless. The magnetic field data can be stored in, for example, a storage 70M. The magnetic field data or the inspection results can be displayed on a display device 70D.

FIG. 3A illustrates the first magnetic field data 11D included in the data 10A obtained from inspection target 80. The first magnetic field data 11D is represented by a first coordinate C1 in the first direction D1 and a second coordinate C2 in the circumferential direction Dc1. The circumferential direction Dc1 is a direction around a first axis Ax1 (see FIG. 1) along the first direction D1. FIG. 3A illustrates the first magnetic field data 11D as two-dimensional data based on the first coordinate C1 and the second coordinate C2. FIG. 3A corresponds to data obtained by expanding cylindrical magnetic field data in the circumferential direction Dc1. In the first magnetic field data 11D, a two-dimensional space 2DS represented by the first coordinate C1 and the second coordinate C2 is formed.

In FIG. 3A, the magnetic field strength in the first magnetic field data 11D is shown by the shading of the image. In this example, the first magnetic field data 11D includes regions of locally high density. It can be presumed that a locally high density region or a locally low density region correspond to defects included in the inspection target 80. For example, a reference value for inspection may be defined for the magnetic field strength included in the first magnetic field data 11D. Inspection may be performed based on the results of comparing the first magnetic field data 11D with the reference value. The comparison result may correspond to the first inspection data DD1 (see FIG. 1), for example.

For example, in the first operation, the processor 70 may be configured to inspect the inspection target 80 based on the first inspection data DD1 which is based on the first magnetic field data 11D.

Furthermore, as described below, in the embodiment, the processor 70 may perform the inspection by inverting a part of the first magnetic field data 11D.

As already explained, in the first magnetic field data 11D, the two-dimensional space 2DS represented by the first coordinate C1 and the second coordinate C2 may be formed (see FIG. 3A). The two-dimensional space 2DS includes a first region r1 and a second region r2. The first magnetic field data 11D includes a first region data Dr1 related to the first region r1 of the two-dimensional space 2DS, and a second region data Dr2 related to the second region r2 of the two-dimensional space 2DS.

The first region r1 and the second region r2 may be determined appropriately depending on the inspection target 80.

As shown in FIG. 3B, the second region data Dr2 is inverted in the direction from the first region r1 to the second region r2 to obtain an inverted data Dv2. In this example, the direction from the first region r1 to the second region r2 is along the circumferential direction Dc1. In this case, the value of the second coordinate C2 of the magnetic field strength included in the second region data Dr2 is inverted.

As shown in FIG. 3C, a difference data 11DF between the inverted data Dv2 of the second region data Dr2 and the first region data Dr1 is derived.

The first magnetic field data 11D may include various noises. Furthermore, the first magnetic field data 11D may include non-uniform magnetic fields caused by the electrodes and the wiring that supplies current to the electrodes. These causes may make it difficult to detect abnormal portions in the inspection target 80.

In the embodiment, the difference data 11DF between the inverted data Dv2 of the second region data Dr2 and the first region data Dr1 is derived. In the difference data 11DF, for example, the effects of noise are suppressed. In the difference data 11DF, the effects of non-uniform magnetic fields caused by electrodes, wiring, etc. are suppressed. This allows the abnormal portion 80D to be detected with high sensitivity. The position of the abnormal portion 80D can be detected with high accuracy. According to the embodiment, it is possible to provide an inspection device capable of highly accurate inspection.

For example, the first inspection data DD1 may include difference data 11DF between the first region data Dr1 and inverted data Dv2 obtained by inverting the second region data Dr2 in the direction from the first region r1 to the second region r2. The processor 70 may inspect the inspection target 80 based on such first inspection data DD1 based on the first magnetic field data 11D.

As shown in FIG. 3A, the two-dimensional space 2DS may include a first position p1, a second position p2, and a third position p3. A direction from the first position p1 to the second position p2 is along the above-mentioned direction from the first region r1 to the second region r2 (in this example, the circumferential direction Dc1). The third position p3 may be the center between the first position p1 and the second position p2 in the direction from the first position p1 to the second position p2.

The first region r1 is between the first position p1 and the third position p3. The second region r2 is between the third position p3 and the second position p2. With this configuration, the size of the first region r1 is the same as the size of the second region r2. The difference data 11DF between the inverted data Dv2 and the first region data Dr1 is efficiently obtained.

As shown in FIG. 3A, the first magnetic field data 11D may include data corresponding to angles from a first angle θ1 to a second angle θ2 in the circumferential direction Dc1. When the direction from the first region r1 to the second region r2 is along the circumferential direction Dc1, the angle of the first position p1 in the circumferential direction Dc1 corresponds to the first angle θ1. The angle of the second position p2 in the circumferential direction Dc1 corresponds to the second angle θ2. The angle of the third position p3 in the circumferential direction Dc1 corresponds to the third angle θ3.

In the embodiment, the angle range of the first magnetic field data 11D in the circumferential direction Dc1 corresponds to the difference between the first angle θ1 and the second angle θ2. In the embodiment, it is preferable that the angle range of the first magnetic field data 11D in the circumferential direction Dc1 is 90degrees or more. This allows the inspection target 80 to be inspected with high accuracy.

It is further preferable that the angle range is 180 degrees or more. The inspection target 80 can be inspected with even higher accuracy. It is further preferable that the angle range is 270 degrees or more. It is further preferable that the angle range is 350 degrees or more. Higher accurate inspection results can be obtained.

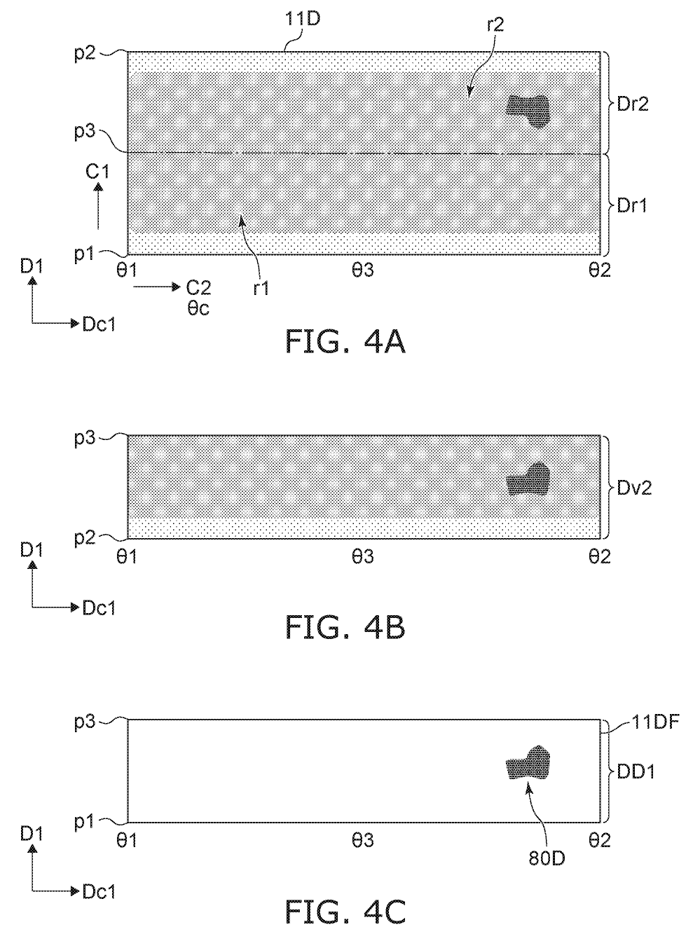

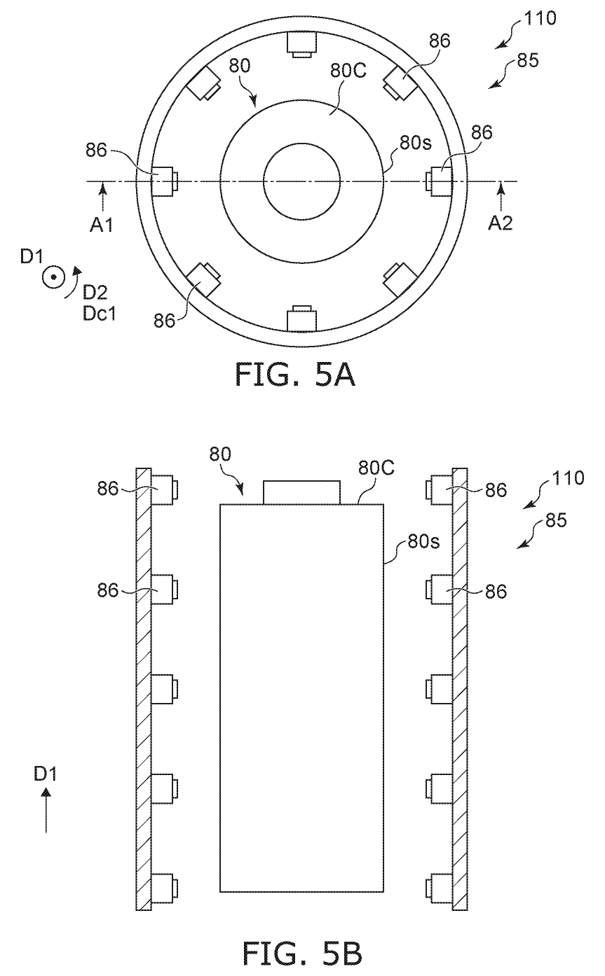

FIGS. 4A to 4C are schematic diagrams illustrating the inspection device according to the first embodiment.

FIG. 4A illustrates the first magnetic field data 11D. In the example shown in FIG. 4A, the direction from the first region r1 to the second region r2 in the first magnetic field data 11D is along the first direction D1.

In this example as well, the first magnetic field data 11D includes first region data Dr1 related to the first region r1 of the two-dimensional space 2DS represented by the first coordinate C1 and the second coordinate C2, and second region data Dr2 related to the second region r2 of the two-dimensional space 2DS.

FIG. 4B illustrates the inverted data Dv2. The inverted data Dv2 is obtained by inverting the second region data Dr2. FIG. 4C shows difference data 11DF between the inverted data Dv2 and the first region data Dr1. Inspection may be performed using the difference data 11DF.

In this case, the first inspection data DD1 also includes the difference data 11DF between the first region data Dr1 and the inverted data Dv2 obtained by inverting the second region data Dr2 in the direction from the first region r1 to the second region r2.

As shown in FIG. 4A, the two-dimensional space 2DS may include the first position p1, the second position p2, and the third position p3. The direction from the first position p1 to the second position p2 is along the direction from the first region r1 to the second region r2 (the first direction D1 in this example). The third position p3 is the center between the first position p1 and the second position p2 in the direction from the first position p1 to the second position p2. The first region r1 is between the first position p1 and the third position p3. The second region r2 is between the third position p3 and the second position p2. The difference data 11DF between the inverted data Dv2 and the first region data Dr1 is efficiently obtained.

In the embodiment, the angle range of the first magnetic field data 11D in the circumferential direction Dc1 is preferably 90 degrees or more. It is more preferable that the angle range is 180 degrees or more. It is more preferable that the angle range is 270 degrees or more. It is more preferable that the angle range is 350 degrees or more.

As shown in FIG. 1, the inspection target 80 may be cylindrical and aligned along the first direction D1. The inspection target 80 is a battery 80C. The inspection device 110 may include the magnetic field sensor 85. The magnetic field sensor 85 is configured to acquire the data 10A obtained from the inspection target 80.

The inspection target 80 includes a cylindrical side face 80s aligned along the first direction D1. The relative position in the circumferential direction Dc1 between the magnetic field sensor 85 and the side face 80s may be configured to change.

As shown in FIG. 1, the magnetic field sensor 85 may include a plurality of sensor elements 86. The position of one of the plurality of sensor elements 86 in the first direction D1 is different from the position of another one of the plurality of sensor elements 86 in the first direction D1. The plurality of sensor elements 86 may be arranged along the first direction D1.

FIGS. 5A and 5B are schematic diagrams illustrating the inspection device according to the first embodiment.

FIG. 5A is a plan view. FIG. 5B is a cross-sectional view taken along the line A1-A2 in FIG. 5A. As shown in FIGS. 5A and 5B, the inspection device 110 includes the magnetic field sensor 85 configured to acquire the data 10A obtained from the inspection target 80. The inspection target 80 is cylindrical along the first direction D1. The magnetic field sensor 85 includes the plurality of sensor elements 86. The plurality of sensor elements 86 are provided around the inspection target 80 in the circumferential direction Dc1.

### Second Embodiment

The second embodiment relates to an inspection method. In the inspection method, the process described with reference to FIG. 2 may be implemented. For example, the inspection method acquires the data 10A obtained from the inspection target 80 and processes the data 10A. The data 10A includes the first magnetic field data 11D represented by the first coordinate C1 in the first direction D1 and the second coordinate C2 in the circumferential direction Dc1 around the first axis Ax1 along the first direction D1. In the inspection method, the inspection target 80 is inspected based on the first inspection data DD1 based on the first magnetic field data 11D.

The first magnetic field data 11D may include the first region data Dr1 related to the first region r1 of the two-dimensional space 2DS represented by the first coordinate C1 and the second coordinate C2, and the second region data Dr2 related to the second region r2 of the two-dimensional space 2DS. The first inspection data DD1 may include the difference data 11DF between the first region data Dr1 and the inverted data Dv2 obtained by inverting the second region data Dr2 in the direction from the first region r1 to the second region r2. Highly accurate inspection can be carried out.

The two-dimensional space 2DS may include the first position p1, the second position p2, and the third position p3. The direction from the first position p1 to the second position p2 is along the direction from the first region r1 to the second region r2. The third position p3 is the center between the first position p1 and the second position p2 in the direction from the first position p1 to the second position p2. The first region r1 is between the first position p1 and the third position p3. The second region r2 is between the third position p3 and the second position p2.

In the second embodiment, for example, the direction from the first region r1 to the second region r2 may be along the circumferential direction Dc1. The direction from the first region r1 to the second region r2 may be along the first direction D1.

### Third Embodiment

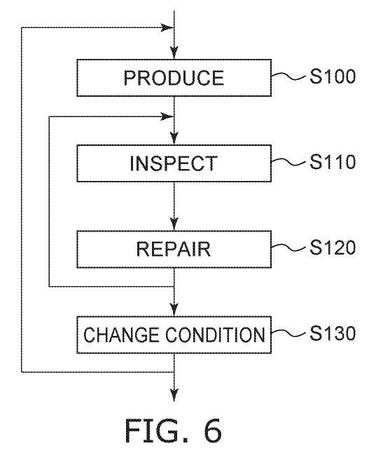

FIG. 6 is a flow chart illustrating a method for manufacturing a battery according to a third embodiment.

As shown in FIG. 6, a battery 80C to be the inspection target 80 is produced (step S100). The battery 80C is inspected by the inspection method according to the second embodiment (step S110). In the inspection, the processes described in relation to the first embodiment and the second embodiment may be carried out. Highly accurate inspection can be performed.

For example, the battery 80C may include the first electrode 81, the second electrode 82, and the battery portion 83 between the first electrode 81 and the second electrode 82. The direction from the first electrode 81 to the second electrode 82 is along the first direction D1 of the first magnetic field data 11D. For example, the first magnetic field data 11D includes the distribution of the magnetic field generated from the battery 80C when an AC voltage is applied between the first electrode 81 and the second electrode 82.

As shown in FIG. 6, repair may be performed based on the inspection results (step S120). The inspection target 80 (battery 80C) after repair may be inspected again.

As shown in FIG. 6, conditions may be changed based on the inspection results (step S130). For example, the conditions include the formation conditions of the battery 80C. For example, the change in conditions may include the change in the material of the battery 80C. For example, the change in conditions may include the design change of the battery 80C. The inspection device 110 and inspection method according to the embodiment may be used for defect analysis of the inspection target 80.

The embodiments may include the following Technical proposals:

### Technical Proposal 1

An inspection device, comprising:

an acquisitor configured to acquire data obtained from an inspection target; and

a processor configured to perform a first operation of processing the data acquired by the acquisitor,

the data including a first magnetic field data represented by a first coordinate in a first direction and a second coordinate in a circumferential direction around a first axis along the first direction, and

the processor being configured to inspect the inspection target based on a first inspection data based on the first magnetic field data in the first operation.

### Technical proposal 2

The inspection device according to Technical proposal 1, wherein

the first magnetic field data includes a first region data related to a first region in a two-dimensional space represented by the first coordinates and the second coordinates, and a second region data related to a second region in the two-dimensional space, and

the first inspection data includes a difference data between the first region data and an inverted data obtained by inverting the second region data in a direction from the first region to the second region.

### Technical proposal 3

The inspection device according to Technical proposal 2, wherein

the two-dimensional space includes a first position, a second position, and a third position,

a direction from the first position to the second position is along a direction from the first region to the second region,

the third position is a center between the first position and the second position in the direction from the first position to the second position,

the first region is between the first position and the third position, and

the second region is between the third position and the second position.

### Technical proposal 4

The inspection device according to Technical proposal 2 or 3, wherein

the direction from the first region to the second region is along the circumferential direction.

### Technical proposal 5

The inspection device according to Technical proposal 2 or 3, wherein

the direction from the first region to the second region is along the first direction.

### Technical proposal 6

The inspection device according to any one of Technical proposals 1 to 5, wherein

an angle range of the first magnetic field data in the circumferential direction is 90 degrees or more.

### Technical proposal 7

The inspection device according to any one of Technical proposals 1 to 5, wherein

an angle range of the first magnetic field data in the circumferential direction is 180 degrees or more.

### Technical proposal 8

The inspection device according to any one of Technical proposals 1 to 5, wherein

an angle range of the first magnetic field data in the circumferential direction is 270 degrees or more.

### Technical proposal 9

The inspection device according to any one of Technical proposals 1 to 8, wherein

the inspection target is cylindrical along the first direction.

### Technical proposal 10

The inspection device according to Technical proposal 9, wherein

the inspection target is a battery.

### Technical proposal 11

The inspection device according to Technical proposal 8 or 9, further comprising:

a magnetic field sensor configured to acquire the data obtained from the inspection target,

the inspection target including a cylindrical side face along the first direction, and

a relative position between the magnetic field sensor and the side face being configured to change in the circumferential direction.

### Technical proposal 12

The inspection device according to Technical proposal 11, wherein

the magnetic field sensor includes a plurality of sensor elements, and

a position of one of the plurality of sensor elements in the first direction is different from a position of another one of the plurality of sensor elements in the first direction.

### Technical proposal 13

The inspection device according to Technical proposal 8 or 9, further comprising:

a magnetic field sensor configured to acquire the data obtained from the inspection target,

the inspection target being cylindrical along the first direction,

the magnetic field sensor including a plurality of sensor elements,

the plurality of sensor elements being arranged around the inspection target in the circumferential direction.

### Technical proposal 14

An inspection method, comprising:

acquiring data obtained from an inspection target;

processing the data, the data including a first magnetic field data represented by a first coordinate in a first direction and a second coordinate in a circumferential direction around a first axis along the first direction; and

inspecting the inspection target based on a first inspection data based on the first magnetic field data.

### Technical proposal 15

The inspection method according to Technical proposal 14, wherein

the first magnetic field data includes a first region data related to a first region in a two-dimensional space represented by the first coordinates and the second coordinates, and a second region data related to a second region in the two-dimensional space, and

the first inspection data includes a difference data between the first region data and an inverted data obtained by inverting the second region data in the direction from the first region to the second region.

### Technical proposal 16

The inspection method according to Technical proposal 15, wherein

the two-dimensional space includes a first position, a second position, and a third position,

a direction from the first position to the second position is along a direction from the first region to the second region,

the third position is a center between the first position and the second position in the direction from the first position to the second position,

the first region is between the first position and the third position, and

the second region is between the third position and the second position.

### Technical proposal 17

The inspection method according to Technical proposal 15 or 16, wherein

the direction from the first region to the second region is along the circumferential direction.

### Technical proposal 18

The inspection method according to Technical proposal 15 or 16, wherein

the direction from the first region to the second region is along the first direction.

### Technical proposal 19

A method for manufacturing a battery, comprising:

producing the battery to be the inspection target; and

inspecting the battery using the inspection method according to any one of Technical proposals 14 to 18.

### Technical proposal 20

The method for manufacturing the battery according to Technical proposal 19, wherein

the battery includes a first electrode, a second electrode, and a battery portion between the first electrode and the second electrode, and

a direction from the first electrode to the second electrode is along the first direction.

According to the embodiment, an inspection device, an inspection method, and a method for manufacturing a battery capable of performing highly accurate inspection can be provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the inspection devices such as acquisitors, processors, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all inspection devices, all inspection methods, and all methods for manufacturing batteries practicable by an appropriate design modification by one skilled in the art based on the inspection devices, inspection methods, and methods for manufacturing batteries described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. An inspection device, comprising:
an acquisitor configured to acquire data obtained from an inspection target; and
a processor configured to perform a first operation of processing the data acquired by the acquisitor,
the data including a first magnetic field data represented by a first coordinate in a first direction and a second coordinate in a circumferential direction around a first axis along the first direction, and
the processor being configured to inspect the inspection target based on a first inspection data based on the first magnetic field data in the first operation.

2. The inspection device according to claim 1, wherein
the first magnetic field data includes a first region data related to a first region in a two-dimensional space represented by the first coordinates and the second coordinates, and a second region data related to a second region in the two-dimensional space, and
the first inspection data includes a difference data between the first region data and an inverted data obtained by inverting the second region data in a direction from the first region to the second region.

3. The inspection device according to claim 2, wherein
the two-dimensional space includes a first position, a second position, and a third position,
a direction from the first position to the second position is along a direction from the first region to the second region,
the third position is a center between the first position and the second position in the direction from the first position to the second position,
the first region is between the first position and the third position, and
the second region is between the third position and the second position.

4. The inspection device according to claim 2, wherein
the direction from the first region to the second region is along the circumferential direction.

5. The inspection device according to claim 2, wherein
the direction from the first region to the second region is along the first direction.

6. The inspection device according to claim 1, wherein
an angle range of the first magnetic field data in the circumferential direction is 90 degrees or more.

7. The inspection device according to claim 1, wherein
an angle range of the first magnetic field data in the circumferential direction is 180 degrees or more.

8. The inspection device according to claim 1, wherein
an angle range of the first magnetic field data in the circumferential direction is 270 degrees or more.

9. The inspection device according to claim 1, wherein
the inspection target is cylindrical along the first direction.

10. The inspection device according to claim 9, wherein
the inspection target is a battery.

11. The inspection device according to claim 8, further comprising:
a magnetic field sensor configured to acquire the data obtained from the inspection target,
the inspection target including a cylindrical side face along the first direction, and
a relative position between the magnetic field sensor and the side face being configured to change in the circumferential direction.

12. The inspection device according to claim 11, wherein
the magnetic field sensor includes a plurality of sensor elements, and
a position of one of the plurality of sensor elements in the first direction is different from a position of another one of the plurality of sensor elements in the first direction.

13. The inspection device according to claim 8, further comprising:
a magnetic field sensor configured to acquire the data obtained from the inspection target,
the inspection target being cylindrical along the first direction,
the magnetic field sensor including a plurality of sensor elements,
the plurality of sensor elements being arranged around the inspection target in the circumferential direction.

14. An inspection method, comprising:
acquiring data obtained from an inspection target;
processing the data, the data including a first magnetic field data represented by a first coordinate in a first direction and a second coordinate in a circumferential direction around a first axis along the first direction; and
inspecting the inspection target based on a first inspection data based on the first magnetic field data.

15. The inspection method according to claim 14, wherein
the first magnetic field data includes a first region data related to a first region in a two-dimensional space represented by the first coordinates and the second coordinates, and a second region data related to a second region in the two-dimensional space, and
the first inspection data includes a difference data between the first region data and an inverted data obtained by inverting the second region data in the direction from the first region to the second region.

16. The inspection method according to claim 15, wherein
the two-dimensional space includes a first position, a second position, and a third position,
a direction from the first position to the second position is along a direction from the first region to the second region,
the third position is a center between the first position and the second position in the direction from the first position to the second position,
the first region is between the first position and the third position, and
the second region is between the third position and the second position.

17. The inspection method according to claim 15, wherein
the direction from the first region to the second region is along the circumferential direction.

18. The inspection method according to claim 15, wherein
the direction from the first region to the second region is along the first direction.

19. A method for manufacturing a battery, comprising:
producing the battery to be the inspection target; and
inspecting the battery using the inspection method according to claim 14.

20. The method for manufacturing the battery according to claim 19, wherein
the battery includes a first electrode, a second electrode, and a battery portion between the first electrode and the second electrode, and
a direction from the first electrode to the second electrode is along the first direction.
